(19) United States
(12) Patent Application Publication
(10) Pub. No.: US 2023/0399492 A1
(43) Pub. Date: Dec. 14, 2023

(54) UNDERFILL COMPOSITION, COATING FILM, CURED FILM, MULTILAYER INTERCONNECTION BOARD, AND MANUFACTURING METHOD OF MULTILAYER INTERCONNECTION BOARD

(71) Applicant: FUJIFILM Corporation, Tokyo (JP)

(72) Inventor: Junji KAWAGUCHI, Haibara-gun (JP)

(73) Assignee: FUJIFILM Corporation, Tokyo (JP)

(21) Appl. No.: 18/456,970

(22) Filed: Aug. 28, 2023

Related U.S. Application Data
(63) Continuation of application No. PCT/JP22/08160, filed on Feb. 28, 2022.

(30) Foreign Application Priority Data
Mar. 10, 2021 (JP) 2021-038088

(51) Int. Cl. C08K 5/3415; H01L 23/00; C08L 33/20

(52) U.S. Cl. CPC C08K 5/3415; H01L 24/26; C08L 33/20; H01L 2224/26

(57) ABSTRACT

An object of the present invention is to provide an underfill composition having excellent temporal stability and good metal adhesiveness, a coating film formed of the underfill composition, a cured film, a multilayer interconnection board, and a manufacturing method of a multilayer interconnection board. The underfill composition of the present invention is an underfill composition containing a polymer and a maleimide compound having a maleimide group, in which the polymer has a cyano group, and a content of the cyano group included in 1 g of the polymer is 0.1 to 6 mmol/g.

### CROSS-REFERENCE TO RELATED APPLICATIONS

This application is a Continuation of PCT International Application No. PCT/JP2022/008160 filed on Feb. 28, 2022, which claims priority under 35 U.S.C. § 119(a) to Japanese Patent Application No. 2021-038088 filed on Mar. 10, 2021. The above applications are hereby expressly incorporated by reference, in their entirety, into the present application.

### BACKGROUND OF THE INVENTION

### 1. Field of the Invention

The present invention relates to an underfill composition, a coating film, a cured film, a multilayer interconnection board, and a manufacturing method of a multilayer interconnection board.

### 2. Description of the Related Art

A metal-filled microstructure (device) in which micropores provided in an insulating base material are filled with a metal is one of fields which have been attracted attention in recent years in nanotechnology, and are expected to be used, for example, as an anisotropically conductive bonding member.

In a case where the anisotropically conductive bonding member is inserted between an electronic component such as a semiconductor element and a circuit board and is simply pressurized, an electrical connection between the electronic component and the circuit board can be obtained, so that the anisotropically conductive bonding member has been widely used as an electrical connecting member of the electronic component or the like such as a semiconductor element or used as a testing connector thereof for carrying out a functional test.

In particular, the electronic component such as a semiconductor element has been significantly downsized, and in a method of directly connecting a wiring board, such as a wire bonding in the related art, a flip-chip bonding, a thermocompression bonding, and the like, since stability of connection cannot be sufficiently guaranteed, the anisotropically conductive bonding member has attracted attention as an electronic connecting member.

As a manufacturing method of a multilayer interconnection board using such an anisotropically conductive bonding member, for example, JP2018-037509A discloses a manufacturing method including a temporary bonding process of bonding the anisotropically conductive bonding member and a wiring board using a non-conductive thermosetting resin (claim 1).

### SUMMARY OF THE INVENTION

As a result of studying on the thermosetting resin disclosed in JP2018-037509A, the present inventor has found that, although adhesiveness between a metal wire and a metal pillar (hereinafter, abbreviated as “metal adhesiveness”) is good, temporal stability may be deteriorated and long work-life may not be ensured.

Therefore, an object of the present invention is to provide an underfill composition having excellent temporal stability and good metal adhesiveness, a coating film formed of the underfill composition, a cured film, a multilayer interconnection board, and a manufacturing method of a multilayer interconnection board.

As a result of intensive studies to achieve the above-described objects, the present inventor has found that, by using a composition which contains a polymer including a specific amount of a cyano group and a maleimide compound, the temporal stability is excellent and the metal adhesiveness is good, and has completed the present invention.

That is, the present inventors have found that the above-described objects can be achieved by the following configurations.
[1] An underfill composition comprising:
a polymer; and
a maleimide compound having a maleimide group,
in which the polymer has a cyano group, and
a content of the cyano group included in 1 g of the polymer is 0.1 to 6 mmol/g.
[2] The underfill composition according to [1],
in which a total content of the polymer and the maleimide compound is 10% to 80% by mass with respect to a total mass of the underfill composition.
[3] The underfill composition according to [1] or [2], further comprising:
a solvent,
in which a component soluble in the solvent is 95% by mass or more with respect to a total mass of a non-volatile component.
[4] The underfill composition according to any one of [1] to [3],
in which the polymer is a thermosetting resin having a curable group other than an epoxy group.
[5] The underfill composition according to any one of [1] to [4],
in which the polymer has a repeating unit, and
the repeating unit has a side chain including a cyano group.
[6] The underfill composition according to any one of [1] to [5],
in which the polymer has a repeating unit represented by Formula (1) described later.
[7] The underfill composition according to any one of [1] to [6],
in which a weight-average molecular weight of the polymer is 100,000 to 1,200,000.

[8] The underfill composition according to any one of [1] to [7],
in which a content of the maleimide compound is 5% to 70% by mass with respect to a total mass of the underfill composition.
[9] The underfill composition according to any one of [1] to [8],
in which the maleimide compound is a compound having two or more maleimide groups in one molecule.
[10] The underfill composition according to any one of [1] to [9],
in which the maleimide compound is a bismaleimide compound.
[11] The underfill composition according to any one of [1] to [10], further comprising:
an allylphenol compound.
[12] The underfill composition according to [11],
in which a content of the allylphenol compound is 3% to 60% by mass with respect to a total mass of the underfill composition.
[13] The underfill composition according to any one of [1] to [12], further comprising:
at least one monomer selected from the group consisting of an acrylic monomer and a methacrylic monomer.
[14] A coating film formed of the underfill composition according to any one of [1] to [13].
[15] A cured film formed by curing the coating film according to [14].
[16] A multilayer interconnection board comprising, in the following order:
a semiconductor element having a plurality of electrodes;
an anisotropically conductive bonding member; and
a circuit board having a plurality of electrodes,
in which the cured film according to is disposed between the semiconductor element and the anisotropically conductive bonding member and between the circuit board and the anisotropically conductive bonding member,
the anisotropically conductive bonding member has an insulating base material consisting of an inorganic material and a plurality of conduction paths consisting of a conductive member, which penetrate through the insulating base material in a thickness direction and are provided in a state of being insulated from each other,
the plurality of conduction paths have a protruding portion protruding from a surface of the insulating base material, and
a height of the plurality of electrodes included in the circuit board is 10 μm or less.
[17] The multilayer interconnection board according to [16],
in which all of the conductive member of the anisotropically conductive bonding member, the plurality of electrodes included in the semiconductor element, and the plurality of electrodes included in the circuit board contain copper.
[18] A manufacturing method of a multilayer interconnection board, in which a multilayer interconnection board having, in the following order, a semiconductor element having a plurality of electrodes, an anisotropically conductive bonding member, and a circuit board having a plurality of electrodes is manufactured, the manufacturing method comprising, in the following order:
a temporary bonding process of bonding the anisotropically conductive bonding member with the semiconductor element and the circuit board using the underfill composition according to any one of [1] to [13];
a main bonding process of electrically bonding the conduction paths included in the anisotropically conductive bonding member with the plurality of electrodes included in the semiconductor element and the plurality of electrodes included in the circuit board by performing heating at a temperature lower than a curing temperature of the underfill composition; and
a curing process of curing the underfill composition by performing heating at a temperature equal to or higher than the curing temperature of the underfill composition,
in which a temperature condition in the temporary bonding process is 20° C. to 140° C., and
a temperature condition in the main bonding process is a temperature higher than a temperature of the temporary bonding process.
[19] The manufacturing method of a multilayer interconnection board according to [18],
in which, in the temporary bonding process, coating films formed of the underfill composition are provided at surfaces of the anisotropically conductive bonding member on the semiconductor element side and on the circuit board side.
[20] The manufacturing method of a multilayer interconnection board according to [18],
in which, in the temporary bonding process, coating films formed of the underfill composition are provided at surfaces of the semiconductor element and the circuit board on the anisotropically conductive bonding member side.
[21] The manufacturing method of a multilayer interconnection board according to any one of to [20],
in which, in the main bonding process, the heating is performed after pressurization or in a pressurized state.

As described above, according to the present invention, it is possible to provide an underfill composition having excellent temporal stability and good metal adhesiveness, a coating film formed of the underfill composition, a cured film, a multilayer interconnection board, and a manufacturing method of a multilayer interconnection board.

### BRIEF DESCRIPTION OF THE DRAWINGS

FIG. 1 is a sectional view of temporarily bonding of an anisotropically conductive bonding member with a semiconductor element and a circuit board, in schematic cross-sectional views for explaining the manufacturing method of a multilayer interconnection board according to the embodiment of the present invention.

FIG. 2 is a sectional view of main bonding of a conduction path of the anisotropically conductive bonding member with electrodes of the semiconductor element and the circuit board, in schematic cross-sectional views for explaining the manufacturing method of a multilayer interconnection board according to the embodiment of the present invention.

FIG. 3 is a sectional view in a case where the underfill composition is cured after the main bonding, in schematic cross-sectional views for explaining the manufacturing method of a multilayer interconnection board according to the embodiment of the present invention.

FIG. 4 is a view showing a classification of evaluation standard for metal adhesiveness.

### DESCRIPTION OF THE PREFERRED EMBODIMENTS

Hereinafter, the present invention will be described in detail.

The description of configuration requirements described below may be made on the basis of representative embodiments of the present invention, but it should not be construed that the present invention is limited to those embodiments.

In the present specification, the numerical value range expressed by “to” means that the numerical values described before and after “to” are included as a lower limit value and an upper limit value, respectively.

In addition, in the present specification, for each component, one kind of substance corresponding to each component may be used alone, or two or more kinds thereof may be used in combination. Here, in a case where two or more kinds of substances are used in combination for each component, the content of the component indicates the total content of the substances used in combination, unless otherwise specified.

In addition, in this specification, “(meth)acrylate” represents a notation of “acrylate” or “methacrylate”, “(meth)acryl” represents a notation of “acryl” or “methacryl”, and “(meth)acryloyl” represents a notation of “acryloyl” or “methacryloyl”.

### Underfill Composition

The underfill composition according to the embodiment of the present invention (hereinafter, also abbreviated as “composition according to the embodiment of the present invention”) is a composition containing a polymer and a maleimide compound having a maleimide group.

In addition, the polymer has a cyano group, and a content of the cyano group included in 1 g of the polymer is 0.1 to 6 mmol/g.

In the present invention, as described above, by using a composition which contains a polymer including a specific amount of a cyano group and a maleimide compound, temporal stability is excellent and metal adhesiveness is good.

The mechanism is not clear in detail, but is presumed to be as follows.

That is, since π adsorption occurs on a metal (particularly, copper) surface due to a coordination of π electrons of the cyano group included in the polymer in a specific amount, it is considered that the metal adhesiveness is good.

In addition, since thermal stability of the maleimide compound is high, and in a manufacturing process of a multilayer interconnection board, even in a case where the composition according to the embodiment of the present invention is left in an applied state, a function as a thermal polymerization initiator is not hindered, it is considered that the temporal stability is good.

In addition, in the present invention, as will be shown in Examples described later, in a case where the composition according to the embodiment of the present invention is used for manufacturing a multilayer interconnection board, it has an unexpected effect of improving bonding suitability.

The mechanism is not clear in detail, but is presumed to be as follows.

That is, since a viscosity of the polymer contained in the composition according to the embodiment of the present invention tends to decrease due to weakening of interaction between the cyano groups in a case of being heated in the temporary bonding process or the main bonding process described later, it is considered that fluidity is enhanced, and the composition according to the embodiment of the present invention is less likely to remain between the conduction path of the anisotropically conductive bonding member and a plurality of electrodes included in the semiconductor element and a plurality of electrodes included in the circuit board.

Hereinafter, the polymer and maleimide compound contained in the composition according to the embodiment of the present invention will be described in detail.

### Polymer

The polymer contained in the composition according to the embodiment of the present invention is a polymer which has a cyano group, in which the content of the cyano group included in 1 g of the polymer is 0.1 to 6 mmol/g.

Here, the content of the cyano group can be measured by a method such as ¹³C-Nuclear Magnetic Resonance (NMR).

In the present invention, the content of the cyano group is preferably 1 to 5 mmol/g.

In the present invention, from the reason that the temporal stability is improved and the metal adhesiveness is improved, it is preferable that the above-described polymer is a thermosetting resin having a curable group other than an epoxy group.

Specific examples of the thermosetting resin having a curable group other than an epoxy group include polyacrylonitrile (including a copolymer with acrylic acid ester or methacrylic acid ester; the same applies hereinafter), an acrylonitrile styrene copolymer (AS) resin, an acrylonitrile butadiene styrene copolymer (ABS) resin, an acrylic resin, a phenol resin, an amino resin (urea resin, melamine resin, and the like), a furan resin, an unsaturated polyester resin, a thermosetting urethane-based resin, a silicone resin, a thermosetting polyimide-based resin, a diallyl phthalate resin, and a vinyl ester resin.

Among these, polyacrylonitrile is preferable.

In the present invention, from the reason that adhesiveness to a metal (particularly, copper) is improved, it is preferable that the above-described polymer has a repeating unit and the repeating unit has a side chain including a cyano group. Specifically, it is more preferable that the above-described polymer has a repeating unit represented by Formula (1).

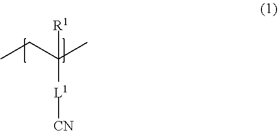

In Formula (1), R¹ represents a hydrogen atom or a substituent, and L¹ represents a single bond or a divalent linking group.

Next, the hydrogen atom or the substituent represented by R¹ in Formula (1) will be described.

In Formula (1), as the substituent represented as one aspect of R¹, a halogen atom, a linear alkyl group having 1 to 20 carbon atoms, a branched or cyclic alkyl group having 3 to 20 carbon atoms, a linear halogenated alkyl group having 1 to 20 carbon atoms, an alkoxy group having 1 to 20 carbon atoms, an aryl group having 6 to 20 carbon atoms, an aryloxy group having 6 to 20 carbon atoms, a cyano group, or an amino group is preferable.

In the present invention, R¹ in Formula (1) is preferably a hydrogen atom or a methyl group, and more preferably a hydrogen atom.

Next, the single bond and the divalent linking group represented by L¹ in Formula (1) will be described.

In Formula (1), as the divalent linking group represented by one aspect of L¹, a divalent linking group obtained by combining at least two or more groups selected from the group consisting of a linear alkylene group having 1 to 18 carbon atoms, which may have a substituent, a branched or cyclic alkylene group having 3 to 18 carbon atoms, which may have a substituent, an arylene group having 6 to 12 carbon atoms, which may have a substituent, an ether group (—O—), a carbonyl group (—C(═O)—), and an imino group (—NH—), which may have a substituent, is preferable.

In the present invention, it is preferable that L¹ in Formula (1) is a single bond.

The above-described polymer may be a homopolymer of a monomer component containing a cyano group (for example, acrylonitrile and the like) (hereinafter, also abbreviated as “cyano group-containing monomer”), but it is preferable that the above-described polymer is a copolymer obtained by copolymerizing the cyano group-containing monomer and a (meth)acrylate component.

Specific examples of the (meth)acrylate component include methyl (meth)acrylate, ethyl (meth)acrylate, butyl (meth)acrylate, isobutyl (meth)acrylate, tert-butyl (meth)acrylate, butoxyethyl (meth)acrylate, isoamyl (meth)acrylate, hexyl (meth)acrylate, 2-ethylhexyl (meth)acrylate, heptyl (meth)acrylate, octylheptyl (meth)acrylate, nonyl (meth)acrylate, decyl (meth)acrylate, undecyl (meth)acrylate, and lauryl (meth)acrylate.

The (meth)acrylate component is introduced in a copolymerization ratio of preferably 70 to 99 mol %, more preferably 80 to 98 mol %, and still more preferably 90 to 98 mol % with respect to the cyano group-containing monomer.

In addition, the above-described polymer may be a copolymer obtained by copolymerizing with another monomer component which is copolymerizable with the above-described (meth)acrylate component, in addition to the above-described cyano group-containing monomer and (meth)acrylate component.

As another monomer component, for example, a carboxyl group-containing monomer (for example, (meth)acrylic acid and the like) can be used.

In the present invention, the above-described polymer can be obtained by polymerizing the above-described monomer components.

A polymerization method is not particularly limited, and examples thereof include solution polymerization, emulsification polymerization, bulk polymerization, and suspension polymerization.

In addition, examples of the type of the polymerization reaction include radical polymerization, cationic polymerization, anionic polymerization, living radical polymerization, living cationic polymerization, living anionic polymerization, and coordination polymerization.

In the present invention, from the viewpoint of solubility in a solvent and ease of liquid handling in coating operation, a weight-average molecular weight (Mw) of the above-described polymer is preferably 100,000 to 1,200,000, and more preferably 500,000 to 1,000,000.

Here, the weight-average molecular weight in the present invention is a value measured by gel permeation chromatography (GPC).
Solvent (eluent): tetrahydrofuran (THF)
Device name: used in combination with Prominence LC-20AD manufactured by
Shimadzu Corporation and RI-104 manufactured by Shodex
Column: used by connecting one TOSOH TSKgel Super HM-M (6.0 mmφ×150 mm)
Column Temperature: 40° C.
Sample concentration: 1 mg/mL
Flow Rate: 0.6 mL/min.
Calibration Curve: A calibration curve made by 5 samples of TSK standard polystyrene manufactured by TOSOH Corporation, Mw of which is 2,630 to 710,000 (Mw/Mn=1.01 to 1.05), is used.

In the present invention, from the reason that voids in the composition can be easily eliminated, low-pressure molding is possible in a semiconductor mounting process, and connectivity is good, a content of the above-described polymer is preferably 10% to 60% by mass, more preferably 10% to 45% by mass, and still more preferably 15% to 40% by mass with respect to the total mass of the composition according to the embodiment of the present invention.

As the above-described polymer, one kind of the polymer may be contained alone, or two or more kinds of the polymers may be contained in combination. In a case where two or more kinds of the polymers are used in combination, it is preferable that the total content of the polymers in the composition is within the above-described range.

### Maleimide Compound

The maleimide compound contained in the composition according to the embodiment of the present invention is not particularly limited as long as it is a compound having a maleimide group, and a low-molecular-weight compound which has a maleimide group and has a molecular weight of 1,000 or less is preferable.

The maleimide compound is, for example, preferably a compound having two or more maleimide groups in one molecule, and more preferably a bismaleimide compound having two maleimide groups in one molecule.

Specific examples of the maleimide compound include 4-methyl-1,3-phenylenebismaleimide, 4,4-bismaleimide diphenylmethane, m-phenylenebismaleimide, bisphenol A diphenyl ether bismaleimide, and 3,3′-dimethyl-5,5′-diethyl-4,4′-diphenylmethane bismaleimide.

Among these, an aromatic bismaleimide is preferable, in particular, considering workability in the temporary bonding process, 3,3′-dimethyl-5,5′-diethyl-4,4′-diphenylmethanebismaleimide, which has good solubility in a solvent and flowability, is preferable.

In the present invention, from the reason that voids in the composition can be easily eliminated, low-pressure molding is possible in a semiconductor mounting process, and connectivity is good, a content of the maleimide compound is preferably 5% to 70% by mass, more preferably 20% to 60% by mass, and still more preferably 20% to 55% by mass with respect to the total mass of the composition according to the embodiment of the present invention.

As the above-described maleimide compound, one kind of the maleimide compound may be contained alone, or two or more kinds of the maleimide compounds may be contained in combination. In a case where two or more kinds of the maleimide compounds are used in combination, it is preferable that the total content of the maleimide compounds in the composition is within the above-described range.

In addition, in the present invention, from the viewpoint of ensuring both curing properties and workability (low viscosity), the total content of the above-described polymer and maleimide compound is preferably 10% to 80% by mass, and more preferably 15% to 70% by mass with respect to the total mass of the underfill composition.

### Allylphenol Compound

From the reason that sufficient curing properties can be obtained, it is preferable that the composition according to the embodiment of the present invention contains an allylphenol compound having an ethylenically unsaturated double bond and a phenolic hydroxyl group.

Examples of the ethylenically unsaturated double bond include a (meth)acryloyl group, a (meth)acrylamide group, a styryl group, a vinyl group (for example, vinyl ester, vinyl ether, and the like), and an allyl group (for example, allyl ether, allyl ester, and the like).

In addition, the phenolic hydroxyl group means a hydroxyl group which substitutes a hydrogen atom in an aromatic ring, and a hydroxyl group which substitutes a hydrogen atom in a benzene ring is preferable.

Examples of the allylphenol compound include allylated bisphenol.

Specific examples of the allylated bisphenol include 2,2′-diallylbisphenol A, 4,4′-(dimethylmethylene)bis[2-(2-propenyl)phenol], 4,4′-methylenebis[2-(2-propenyl)phenol], and 4,4′-(dimethylmethylene)bis[2-(2-propenyl)-6-methylphenol], and among these, 2,2′-diallylbisphenol A is preferable.

In the present invention, from the reason that it is easy to eliminate voids in the composition and connectivity is improved, a content of the allylphenol compound is preferably 3% to 60% by mass, more preferably 6% to 55% by mass, and still more preferably 6% to 50% by mass with respect to the total mass of the composition according to the embodiment of the present invention.

As the above-described allylphenol compound, one kind of the allylphenol compound may be contained alone, or two or more kinds of the allylphenol compounds may be contained in combination. In a case where two or more kinds of the allylphenol compounds are used in combination, it is preferable that the total content of the allylphenol compounds in the composition is within the above-described range.

### Monomer

From the viewpoint of ensuring both curing properties and workability (low viscosity), it is preferable that the composition according to the embodiment of the present invention contains at least one monomer selected from the group consisting of an acrylic monomer or a methacrylic monomer.

As the above-described monomer, either a monofunctional (meth)acrylate having one (meth)acryloyl group or a polyfunctional (meth)acrylate having two or more (meth)acryloyl groups can be used.

Examples of the above-described monomer include isocyanuric acid EO-modified diacrylate, isocyanuric acid EO-modified triacrylate, dipentaerythritol tetraacrylate, 2-hydroxy-3-phenoxypropyl acrylate, 9,9-bis[4-(2-acryloyloxyethoxy)phenyl]fluorene, tricyclodecane dimethanol diacrylate, ethoxylated bisphenol A diacrylate, and fluorene-based acrylate (for example, product names: OGSOL EA0200 and EA0300 manufactured by Osaka Gas Chemicals Co., Ltd.).

Among these monomers, in consideration of heat resistance and the like, a fluorene-based acrylate, which has high heat resistance, is preferable.

In the present invention, a content of the above-described monomer is preferably 15% by mass or less with respect to the total mass of the polymer, the maleimide compound, and the allylphenol compound.

As the above-described monomer, one kind of the monomer may be contained alone, or two or more kinds of the monomers may be contained in combination. In a case where two or more kinds of the monomers are used in combination, it is preferable that the total content of the monomers in the composition is within the above-described range.

### Solvent

From the reason that workability is good, it is preferable that the composition according to the embodiment of the present invention contains a solvent.

Examples of the solvent include organic solvents such as ketones (such as acetone, methyl ethyl ketone, 2-butanone, methyl isobutyl ketone, cyclopentanone, cyclohexanone, and acetylacetone), ethers (such as dioxane, tetrahydrofuran, tetrahydropyran, dioxolane, tetrahydrofurfuryl alcohol, cyclopentyl methyl ether, and dibutyl ether), aliphatic hydrocarbons (such as hexane), alicyclic hydrocarbons (such as cyclohexane), aromatic hydrocarbons (such as benzene, toluene, xylene, tetralin, and trimethylbenzene), halogenated carbons (such as dichloromethane, trichloromethane (chloroform), dichloroethane, dichlorobenzene, 1,1,2,2-tetrachloroethane, and chlorotoluene), esters (such as methyl acetate, ethyl acetate, butyl acetate, diethyl carbonate, ethyl acetoacetate, n-pentyl acetate, ethyl benzoate, benzyl benzoate, butyl carbitol acetate, diethylene glycol monoethyl ether acetate, and isoamyl acetate), alcohols (such as ethanol, isopropanol, butanol, cyclohexanol, furfuryl alcohol, 2-ethylhexanol, octanol, benzyl alcohol, ethanolamine, ethylene glycol, propylene glycol, diethylene glycol, diethylene glycol monomethyl ether, diethylene glycol monoethyl ether, and diethylene glycol monobutyl ether), phenols (such as phenol and cresol), cellosolves (such as methyl cellosolve, ethyl cellosolve, and 1,2-dimethoxyethane), cellosolve acetates, sulfoxides (such as dimethylsulfoxide), amides (such as dimethylformamide, dimethylacetamide, N-methylpyrrolidone, N-ethylpyrrolidone, and 1,3-dimethyl-2-imidazolidinone), and heterocyclic compounds (such as pyridine and 2,6-lutidine); and water.

These solvents may be used alone or in combination of two or more.

From the reason that workability is good, it is preferable that, in the composition according to the embodiment of the present invention, a component soluble in the solvent is 95% by mass or more with respect to the total mass of a non-volatile component.

Here, the non-volatile component means a component constituting the composition, other than the solvent.

### Other Components

The composition used for the underfill material may contain, depending on the purpose, various additives such as an antioxidant, a migration inhibitor, an inorganic filler, a dispersant, a buffer, and a viscosity adjuster, in addition to the above-described components.

### Coating Film

The coating film according to the embodiment of the present invention is a coating film formed of the above-described composition according to the embodiment of the present invention.

Here, the coating film means an uncured film (resin layer) in which the above-described composition according to the embodiment of the present invention is applied and the solvent is removed by drying.

A thickness of the coating film according to the embodiment of the present invention is not particularly limited, and from the viewpoint of, in the manufacturing method of a multilayer interconnection board according to the embodiment of the present invention described later, following a surface shape of the semiconductor element and the circuit board to be connected, it is preferably 50 to 3,000 nm and more preferably 250 to 2,000 nm.

A method for forming the coating film according to the embodiment of the present invention is not particularly limited, but in a case of being provided at surfaces of the anisotropically conductive bonding member on the semiconductor element side and on the circuit board side, which will be described later, examples thereof include a method of applying the above-described composition according to the embodiment of the present invention onto a surface of the insulating base material and a protruding portion of the conduction path, drying the composition, and performing baking as necessary.

A method for applying the composition according to the embodiment of the present invention is not particularly limited, and for example, known coating method in the related art, such as a gravure coating method, a reverse coating method, a die coating method, a blade coating method, a roll coating method, an air knife coating method, a screen coating method, a bar coating method, and a curtain coating method, can be used.

In addition, a drying method after the applying is not particularly limited, and examples thereof include a heating treatment at a temperature of 0° C. to 100° C. for several seconds to several tens of minutes in the atmosphere and a heating treatment at a temperature of 0° C. to 80° C. under reduced pressure for ten minutes to several hours.

In addition, a baking method after the drying is not particularly limited because it varies depending on the material to be used, and examples thereof include a heating treatment at a temperature of 160° C. to 300° C. for 2 minutes to 6 hours.

### Cured Film

The cured film according to the embodiment of the present invention is a cured film formed by curing the above-described coating film according to the embodiment of the present invention.

Here, a method for forming the cured film is not particularly limited, and examples thereof include a method of performing heating at a temperature equal to or higher than a curing temperature of the above-described composition according to the embodiment of the present invention.

In addition, a heating temperature in the method for forming the cured film is preferably 200° C. or higher and 400° C. or lower, and more preferably 200° C. or higher and 300° C. or lower.

In addition, from the viewpoint of sufficiently advancing the curing, a heating time in the method for forming the cured film is preferably 1 to 60 minutes.

### Multilayer Interconnection Board

The multilayer interconnection board according to the embodiment of the present invention is a multilayer interconnection board including, in the following order, a semiconductor element having a plurality of electrodes, an anisotropically conductive bonding member, and a circuit board having a plurality of electrodes.

In addition, in the multilayer interconnection board according to the embodiment of the present invention, the above-described cured film is disposed between the semiconductor element and the anisotropically conductive bonding member and between the circuit board and the anisotropically conductive bonding member.

In addition, the anisotropically conductive bonding member has an insulating base material consisting of an inorganic material and a plurality of conduction paths consisting of a conductive member, which penetrate through the insulating base material in a thickness direction and are provided in a state of being insulated from each other, and the plurality of conduction paths have a protruding portion protruding from a surface of the insulating base material.

In addition, a height of the plurality of electrodes included in the circuit board is 10 μm or less.

### Anisotropically Conductive Bonding Member

As described above, the anisotropically conductive bonding member included in the multilayer interconnection board according to the embodiment of the present invention includes an insulating base material consisting of an inorganic material and a plurality of conduction paths consisting of a conductive member, which penetrate through the insulating base material in a thickness direction and are provided in a state of being insulated from each other.

In addition, each of the conduction paths has a protruding portion protruding from a surface of the insulating base material.

In the present invention, as the anisotropically conductive bonding member and the manufacturing method thereof, the anisotropically conductive bonding member and the manufacturing method thereof disclosed in JP2018-037509A can be adopted, the contents of which are incorporated herein by reference.

In addition, as the manufacturing method of the anisotropically conductive bonding member, methods other than a method disclosed in JP2018-037509A can also be used, and for example, a method described in JP2008-270157A, a method described in WO2017/057150A, a method described in WO2018/155273A, a method described in JP2019-153415A, and the like can be used. The contents described in these publications are incorporated herein by reference.

### Semiconductor Element

As described above, the semiconductor element included in the multilayer interconnection board according to the embodiment of the present invention is a semiconductor element having a plurality of electrodes.

In the present invention, a known semiconductor element in the related art can be adopted as the semiconductor element, and specific examples thereof include a logic large scale integration (logic LSI) (for example, an application specific integrated circuit (ASIC), a field programmable gate array (FPGA), or an application specific standard product (ASSP)), a microprocessor (for example, a central processing unit (CPU) or a graphics processing unit (GPU)), a memory (for example, a dynamic random access memory (DRAM), a hybrid memory cube (HMC), a magnetic memory (magnetic RAM; MRAM), a phase-change memory (PCM), a resistive memory (resistive RAM; ReRAM), a ferroelectric RAM (FeRAM: a ferroelectric memory), or flash memory (not AND (NAND) flash)), a light emitting diode (LED) (for example, a micro flash of a mobile terminal, in-vehicle use, a projector light source, an LCD backlight, or general lighting use), a power device, analog integrated circuit (IC), (for example, a direct current (DC)-direct current (DC) converter, or an insulated gate bipolar transistor (IGBT)), micro electro mechanical systems (MEMS), (for example, an acceleration sensor, a pressure sensor, an oscillator, or a gyro sensor), wireless (for example, a global positioning system (GPS), a frequency modulation (FM), a near field communication (NFC), an RF expansion module (RFEM), a monolithic microwave integrated circuit (MIMIC), or a wireless local area network (WLAN)), and a discrete element, back side Illumination (BSI), a contact image sensor (CIS), a camera module, a complementary metal oxide semiconductor (CMOS), a passive device, a surface acoustic wave (SAW) filter, a radio frequency (RF) filter, a radio frequency integrated passive device (RFIPD), and broadband (BB).

The semiconductor element is, for example, one complete unit, and the semiconductor element alone exhibits a specific function such as a circuit and a sensor. The semiconductor element may have an interposer function. In addition, for example, it is possible to stack a plurality of devices such as a logic chip having a logic circuit and a memory chip on a device having an interposer function. Furthermore, in this case, even in a case where the electrode size is different for each device, the bonding can be carried out.

### Circuit Board

The circuit board included in the multilayer interconnection board according to the embodiment of the present invention has a substrate and a plurality of electrodes having a height of 10 μm or less, and further has other members as necessary.

Here, the height of the electrode refers to an average value obtained by observing a cross section of the circuit board with a field emission scanning electron microscope at a magnification of 10,000 times and measuring the height of the electrode at 10 points.

In addition, the circuit board may be a semiconductor element in which an integrated circuit is mounted on a substrate (for example, a silicon substrate). Examples of the semiconductor element are as described above.

### Substrate

The substrate is not particularly limited and may be appropriately selected depending on the intended purpose, and examples thereof include a plastic substrate and a glass substrate.

In addition, the shape, size, and structure of the substrate are not particularly limited and can be appropriately selected depending on the intended purpose.

### Electrode

Examples of a material of the electrode include gold, silver, copper, and aluminum.

In addition, the shape of the electrode is not particularly limited as long as the height thereof is 10 μm or less, and may be a wiring shape, which can be appropriately selected depending on the purpose.

In addition, the height of the electrode is preferably 0.05 μm or more, and more preferably 0.1 to 5 μm.

### Cured Film

The cured film included in the multilayer interconnection board according to the embodiment of the present invention is the above-described cured film according to the embodiment of the present invention.

Here, a thickness of the cured film in the multilayer interconnection board according to the embodiment of the present invention is not particularly limited, but is preferably 50 to 3,000 nm and more preferably 250 to 2,000 nm.

In the present invention, from the reason that the effect of the present invention is prominent, it is preferable that all of the conductive member of the anisotropically conductive bonding member, the plurality of electrodes included in the semiconductor element, and the plurality of electrodes included in the circuit board contain copper.

### Manufacturing Method of Multilayer Interconnection Board

The manufacturing method of the multilayer interconnection board according to the embodiment of the present invention (hereinafter, abbreviated as “manufacturing method according to the embodiment of the present invention”) is a manufacturing method of a multilayer interconnection board including, in the following order, a semiconductor element having a plurality of electrodes, an anisotropically conductive bonding member, and a circuit board having a plurality of electrodes.

In addition, the manufacturing method according to the embodiment of the present invention includes, in the following order, a temporary bonding process of bonding the above-described anisotropically conductive bonding member with the above-described semiconductor element and the above-described circuit board using the above-described composition according to the embodiment of the present invention; a main bonding process of electrically bonding the conduction paths included in the above-described anisotropically conductive bonding member with the plurality of electrodes included in the above-described semiconductor element and the plurality of electrodes included in the above-described circuit board by performing heating at a temperature lower than a curing temperature of the above-described composition according to the embodiment of the present invention; and a curing process of curing the above-described composition according to the embodiment of the present invention by performing heating at a temperature equal to or higher than the curing temperature of the above-described composition according to the embodiment of the present invention.

In addition, a temperature condition in the temporary bonding process is 20° C. to 140° C.

In addition, a temperature condition in the main bonding process is a temperature higher than a temperature of the temporary bonding process.

The anisotropically conductive bonding member, semiconductor element, and circuit board used in the manufacturing method according to the embodiment of the present invention are the same as those described in the multilayer interconnection board according to the embodiment of the present invention above.

Hereinafter, the temporary bonding process, the main bonding process, and the curing process included in the manufacturing method according to the embodiment of the present invention will be described in detail.

### Temporary Bonding Process

The temporary bonding process included in the manufacturing method according to the embodiment of the present invention is a process of bonding the above-described anisotropically conductive bonding member with the above-described semiconductor element and circuit board using the above-described composition according to the embodiment of the present invention under a temperature condition of 20° C. to 140° C.

In the present invention, in a case of applying the above-described composition according to the embodiment of the present invention, the above-described coating films formed of the composition according to the embodiment of the present invention may be provided at surfaces of the above-described anisotropically conductive bonding member on the above-described semiconductor element side and on the above-described circuit board side, or may be provided at surfaces of the above-described semiconductor element and circuit board on the above-described anisotropically conductive bonding member side.

In the present invention, from the reason that misalignment caused by resin softening due to the heating is prevented, it is preferable that the heating at 20° C. to 140° C. is performed after pressurization or in a pressurized state.

The temperature condition in the temporary bonding process is not particularly limited as long as it is 20° C. to 140° C., preferably 25° C. to 100° C.

In addition, a pressurizing condition in a case of pressurizing in the temporary bonding process is not particularly limited, but is preferably 10 MPa or less and more preferably 6 MPa or less.

In the present invention, it is preferable that the temporary bonding process is performed by a chip on wafer (CoW) process. A semiconductor wafer and a semiconductor chip wafer are investigated to divide good chips and defective chips in advance (Known Good Die; KGD) and only good chips of the semiconductor chip wafer are bonded to a good portion in the semiconductor wafer so that loss can be reduced. In a case of the temporary bonding, since the misalignment occurs in steps (such as a transport step) before main bonding at a weak temporary bonding strength, the above-described temperature condition and pressurizing condition in the temporary bonding process are important.

### Main Bonding Process

The main bonding process included in the manufacturing method according to the embodiment of the present invention is a process of electrically bonding the conduction paths included in the above-described anisotropically conductive bonding member with the plurality of electrodes included in the above-described semiconductor element and the plurality of electrodes included in the above-described circuit board by performing heating at a temperature lower than the curing temperature of the above-described composition according to the embodiment of the present invention and higher than the temperature of the temporary bonding process.

In the present invention, from the reason that misalignment caused by resin softening due to the heating is prevented, it is preferable that the heating at the temperature equal to lower than the curing temperature of the above-described composition according to the embodiment of the present invention is performed after pressurization or in a pressurized state.

The temperature condition in the main bonding process is not particularly limited as long as it is a temperature higher than the temperature of the temporary bonding process, but is preferably higher than 100° C. and 300° C. or lower, and more preferably 120° C. to 250° C.

In addition, a pressurizing condition in a case of pressurizing in the main bonding process is not particularly limited, but is preferably 150 MPa or less and more preferably 0.1 to 100 MPa.

In addition, a time of the main bonding process is not particularly limited; however, it is preferably 1 second to 60 minutes and more preferably 5 seconds to 40 minutes.

By performing the main bonding process under the above-described conditions, the composition according to the embodiment of the present invention used in the above-described temporary bonding process tends to flow between the electrodes of the semiconductor element and the circuit board, and is less likely to remain in a bonded portion.

The main bonding process may be performed for each chip of the semiconductor element, but from the viewpoint that tact time can be reduced, it is preferable to perform the main bonding process on wafers collectively.

### Curing Process

The curing process included in the manufacturing method according to the embodiment of the present invention is a process of curing the above-described composition according to the embodiment of the present invention by performing heating at a temperature equal to or higher than the curing temperature of the above-described composition according to the embodiment of the present invention.

In the present invention, the temperature condition in the curing process is not particularly limited as long as it is equal to or higher than the curing temperature of the above-described composition according to the embodiment of the present invention, but is preferably 200° C. or higher and 400° C. or lower, and more preferably 200° C. or higher and 300° C. or lower.

In addition, from the reason that the misalignment caused by resin softening due to the heating is prevented, it is preferable that the heating during the curing process is performed after pressurization or in a pressurized state.

In addition, a time of the curing process is not particularly limited, but from the viewpoint of sufficiently advancing the curing of the above-described composition according to the embodiment of the present invention, it is preferably 1 to 60 minutes.

Same as the main bonding process, the curing process may be performed for each chip of the semiconductor element, but from the viewpoint that tact time can be reduced, it is preferable to perform the curing process on wafers collectively.

In addition, a pressurizing condition in a case of pressurizing in the curing process is not particularly limited, but is preferably 150 MPa or less and more preferably 0.1 to 100 MPa.

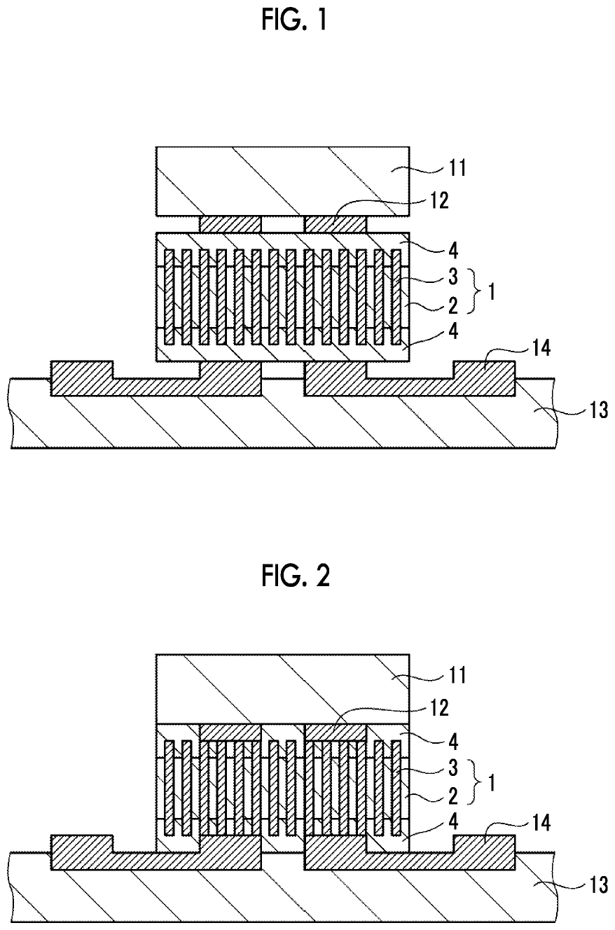

Next, the temporary bonding process, the main bonding process, the curing process, and the like described above will be described with reference to FIGS. 1 to 3.

As shown in FIG. 1, an anisotropically conductive bonding member 1 (reference numeral 2: insulating base material, reference numeral 3: conduction path) are temporarily bonded with a semiconductor element 11 and a circuit board 13 using an underfill composition 4 provided on a surface of the anisotropically conductive bonding member 1.

Next, as shown in FIG. 2, the conduction paths 3 included in the anisotropically conductive bonding member 1 with a plurality of electrodes 12 included in the semiconductor element 11 and a plurality of electrodes 14 included in the circuit board 13 are electrically bonded (main-bonded) by performing heating at a temperature lower than a curing temperature of the underfill composition 4.

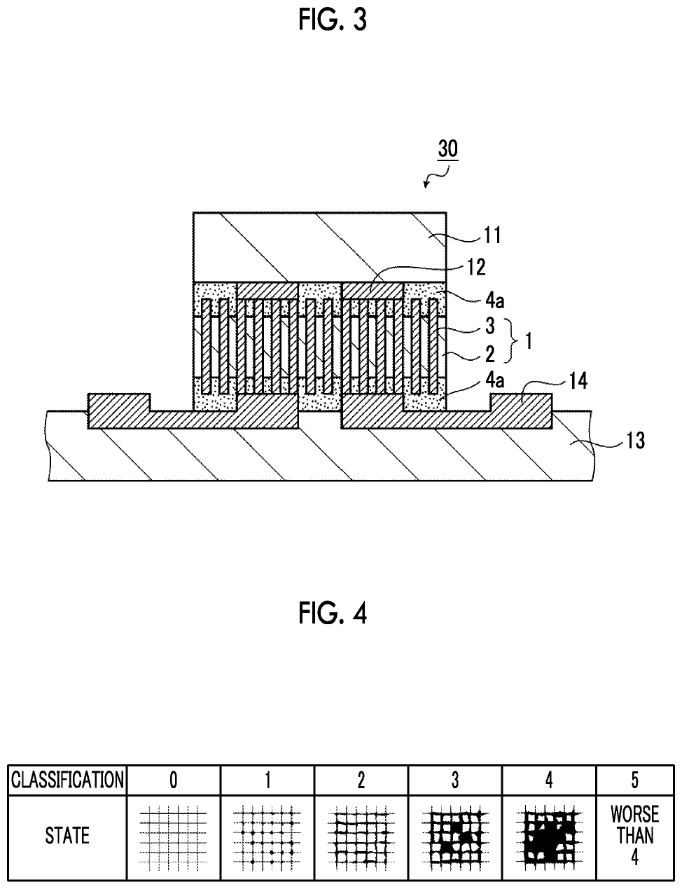

Next, as shown in FIG. 3, a multilayer interconnection board 30 can be manufactured by performing heating at a temperature equal or higher than the curing temperature of the underfill composition 4 to cure the underfill composition 4.

### EXAMPLES

Hereinafter, the present invention will be described in more detail with reference to examples. Materials, amounts used, ratios, treatment contents, treatment procedures, and the like shown in the following examples can be appropriately changed without departing from the spirit of the present invention. Accordingly, the scope of the present invention should not be construed as being limited to the following examples.

### Production of Anisotropically Conductive Bonding Member

### Production of Aluminum Substrate

A molten metal was produced using an aluminum alloy containing 0.06% by mass of Si, 0.30% by mass of Fe, 0.005% by mass of Cu, 0.001% by mass of Mn, 0.001% by mass of Mg, 0.001% by mass of Zn, and 0.03% by mass of Ti and, as the remainder, Al and unavoidable impurities, a molten metal treatment and filtration were performed, and an ingot having a thickness of 500 mm and a width of 1,200 mm was produced according to a direct chill (DC) casting method.

Next, the surface was scraped off using a surface grinder having an average thickness of 10 mm and heated at 550° C. and maintained the state for approximately 5 hours. After the temperature was decreased to 400° C., a rolled sheet having a thickness of 2.7 mm was obtained using a hot rolling mill.

Furthermore, a heat treatment was performed thereon at 500° C. using a continuous annealing machine, and a cold rolling was performed so that a thickness was finished to 1.0 mm, thereby obtaining an aluminum substrate of Japanese Industrial Standards (JIS) 1050 material.

After the aluminum substrate was formed to have a width of 1030 mm, each of the following treatments was performed.

### Electropolishing Treatment

The above-described aluminum substrate was subjected to an electropolishing treatment using an electropolishing liquid having the following composition under conditions of a voltage of 25 V, a liquid temperature of 65° C., and a liquid flow rate of 3.0 m/min.

A carbon electrode was used as a cathode, and GP0110-30R (manufactured by TAKASAGO Ltd.) was used as a power source. In addition, the flow rate of the electrolytic solution was measured using a vortex flow monitor FLM22-10PCW (manufactured by AS ONE Corporation).

(Composition of electropolishing liquid)

| | |
|---|---|
| 85% by mass of phosphoric acid (reagent manufactured by | 660 mL |
| FUJIFILM Wako Pure Chemical Corporation) | |
| Pure water | 160 mL |
| Sulfuric acid | 150 mL |
| Ethylene glycol | 30 mL |

### Anodization Treatment Step

Next, the aluminum substrate after the electropolishing treatment was subjected to an anodization treatment by a self-ordering method according to the procedure described in JP2007-204802A.

The aluminum substrate after the electropolishing treatment was subjected to a pre-anodization treatment for 5 hours using an electrolytic solution of 0.50 mol/L oxalic acid under conditions of a voltage of 40 V, a liquid temperature of 16° C., and a liquid flow rate of 3.0 m/min.

Thereafter, the aluminum substrate subjected to the pre-anodization treatment was immersed for 12 hours in a mixed aqueous solution (liquid temperature: 50° C.) of 0.2 mol/L of chromic acid anhydride and 0.6 mol/L phosphoric acid to perform a film removal treatment.

Thereafter, the aluminum substrate was subjected to a re-anodization treatment for 3 hours and 45 minutes using an electrolytic solution of 0.50 mol/L oxalic acid under conditions of a voltage of 40 V, a liquid temperature of 16° C., and a liquid flow rate of 3.0 m/min to obtain an anodized film having a thickness of 30 μm.

In the pre-anodization treatment and the re-anodization treatment, a stainless steel electrode was used as a cathode, and GP0110-30R (manufactured by TAKASAGO Ltd.) was used as a power source. In addition, NeoCool BD36 (manufactured by Yamato Scientific Co., Ltd.) was used as a cooling device, and PAIRSTIRRER PS-100 (manufactured by TOKYO RIKAKIKAI CO., LTD.) was used as a stirring and heating device. Furthermore, the flow rate of the electrolytic solution was measured using a vortex flow monitor FLM22-10PCW (manufactured by AS ONE Corporation).

### Barrier Layer Removing Step

Next, after the anodization treatment step, using an alkaline aqueous solution obtained by dissolving zinc oxide in an sodium hydroxide aqueous solution (50 g/L) to a concentration of 2,000 ppm, an etching treatment was performed by immersion at 30° C. for 150 seconds to remove a barrier layer at a bottom of micropores of the anodized film and deposit zinc on the exposed surface of the aluminum substrate at the same time.

In addition, an average thickness of the anodized film after the barrier layer removing step was 30 μm.

### Metal Filling Step

Next, the aluminum substrate was used as a cathode, and platinum was used as a positive electrode for an electrolytic plating treatment.

Specifically, a copper plating liquid having the composition shown below was used, and constant current electrolysis was carried out to produce a metal-filled microstructure in which nickel was filled inside the micropores. Here, for the constant current electrolysis, a plating device manufactured by YAMAMOTO-MS Co., Ltd. was used, and a power source (HZ-3000) manufactured by HOKUTO DENKO Corporation was used, cyclic voltammetry was carried out in the plating liquid, and then after checking precipitation potential, the treatment was carried out under the conditions shown below.

(Condition and conditions of copper plating liquid)

| | | |
|---|---|---|
| Copper sulfate | 100 | g/L |
| Sulfuric acid | 50 | g/L |
| Hydrochloric acid | 15 | g/L |
| Temperature | 25° | C. |
| Current density | 10 | A/dm² |

The surface of the anodized film after filling the micropores with a metal was observed with FE-SEM, and in a case where the presence or absence of sealing with metal in 1000 micropores was observed to calculate a sealing rate (the number of micropores to be sealed/1000), it was 98%.

In addition, in a case where the anodized film after filling the micropores with metal was cut with FIB in a thickness direction and a cross section thereof was imaged with FE-SEM (magnification: 50,000 times) to confirm the inside of the micropores, it was found that the inside of the sealed micropores was completely filled with the metal.

### Surface Metal Protruding Step

The structure after the metal filling step was immersed in an aqueous solution of sodium hydroxide (concentration: 5% by mass, liquid temperature: 20° C.), the immersion time was adjusted such that a height of the protruding portion was 400 nm, whereby a structure was produced by selectively dissolving the surface of the aluminum anodized film and protruding copper which was a filling metal.

### Resin Layer Forming Step

A heat-peelable resin base material with a pressure-sensitive adhesive layer (REVALPHA 3195MS, manufactured by Nitto Denko Corporation) was attached to a surface on a side in which the aluminum substrate was not provided.

### Substrate Removing Step

Next, the aluminum substrate was dissolved and removed by immersing the aluminum substrate in a mixed solution of copper chloride and hydrochloric acid to produce a metal-filled microstructure having an average thickness of 30 μm.

In the produced metal-filled microstructure, a diameter of the conduction path was 60 nm, a pitch between the conduction paths was 100 nm, and a density of the conduction path was 57.7 million pieces/mm².

### Back Surface Metal Protruding Step

The structure after the substrate removing step was immersed in an aqueous solution of sodium hydroxide (concentration: 5% by mass, liquid temperature: 20° C.), the immersion time was adjusted such that a height of the protruding portion was 400 nm, whereby an anisotropically conductive bonding member was produced by selectively dissolving the surface of the aluminum anodized film and protruding copper which was a filling metal.

### Example 1

### Underfill Composition

An underfill composition 1 having the following composition was prepared. The content of the cyano group in the synthesized ethyl acrylate/acrylonitrile copolymer is shown in Table 1 below.

Underfill composition 1

| | |
|---|---|
| Methyl ethyl ketone | 50 parts by mass |
| Ethyl acrylate/acrylonitrile copolymer (Mw: 160,000, | 16 parts by mass |
| copolymer molar ratio: 95:5) | |
| Maleimide compound (product name: BMI 5100, | 22 parts by mass |
| manufactured by Daiwa Kasei Industry Co., Ltd.) | |
| Bisallylphenol (product name: DABPA, manufactured | 12 parts by mass |
| by Daiwa Kasei Industry Co., Ltd.) | |

After peeling off the peelable resin base material with a pressure-sensitive adhesive layer (REVALPHA 3195MS, manufactured by Nitto Denko Corporation), which had been provided on the surface of the anisotropically conductive bonding member produced above, the prepared underfill composition 1 was applied onto the surface (exposed surface) and the back surface with a spin coater so as to have a thickness of 400 nm.

A TEG chip (daisy chain pattern) manufactured by WALTS CO., LTD. and an interposer were prepared, and these were installed above and below a chip bonder to adjust alignment in advance.

After the alignment adjustment, the produced anisotropically conductive bonding member was superposed on a Cu post side of the interposer installed on the lower side, and using a room-temperature bonding apparatus (WP-100, manufactured by PMT Corporation), temporary bonding was performed by thermocompression under conditions of a temperature of 100° C., 1 minute, and 6 MPa.

Next, the temporarily bonded sample was main-bonded by thermocompression using the room-temperature bonding apparatus (WP-100, manufactured by PMT Corporation) under conditions of a temperature of 180° C., 5 minutes, and 50 MPa.

Next, thermocompression was performed under conditions of a temperature of 220° C., 25 minutes, and 50 MPa to cure the underfill composition, thereby producing a multilayer interconnection board.

### Example 2

A multilayer interconnection board was produced in the same manner as in Example 1, except that the copolymerization molar ratio of the ethyl acrylate/acrylonitrile copolymer was changed to 85:15.

### Example 3

A multilayer interconnection board was produced in the same manner as in Example 1, except that the copolymerization molar ratio of the ethyl acrylate/acrylonitrile copolymer was changed to 75:25.

### Example 4

A multilayer interconnection board was produced in the same manner as in Example 1, except that the copolymerization molar ratio of the ethyl acrylate/acrylonitrile copolymer was changed to 99:1.

### Example 5

A multilayer interconnection board was produced in the same manner as in Example 1, except that the underfill composition 1 was changed to the following underfill composition 2.

Underfill composition 2

| | |
|---|---|
| Methyl ethyl ketone | 50 parts by mass |
| Ethyl acrylate/acrylonitrile copolymer (Mw: 160,000, | 16 parts by mass |
| copolymer molar ratio: 95:5) | |
| Maleimide compound (product name: BMI 5100, | 22 parts by mass |
| manufactured by Daiwa Kasei Industry Co., Ltd.) | |
| Bisallylphenol (product name: DABPA, manufactured | 8 parts by mass |
| by Daiwa Kasei Industry Co., Ltd.) | |
| Fluorene-based acrylate (product name: OGSOL | 4 parts by mass |
| EA0200 and EA0300, manufactured by Osaka Gas | |
| Chemicals Co., Ltd.) | |

### Example 6

A multilayer interconnection board was produced in the same manner as in Example 1, except that the underfill composition 1 was changed to the following underfill composition 3.

Underfill composition 3

| | |
|---|---|
| Methyl ethyl ketone | 50 parts by mass |
| Ethyl acrylate/acrylonitrile copolymer (Mw: 160,000, | 16 parts by mass |
| copolymer molar ratio: 95:5) | |
| Maleimide compound (product name: BMI 5100, | 20 parts by mass |
| manufactured by Daiwa Kasei Industry Co., Ltd.) | |
| Bisallylphenol (product name: DABPA, manufactured | 8 parts by mass |
| by Daiwa Kasei Industry Co., Ltd.) | |
| Silica particles (product name: AEROSIL R202, | 6 parts by mass |
| manufactured by Nippon Aerosil Co., Ltd.) | |

### Example 7

A multilayer interconnection board was produced in the same manner as in Example 1, except that a composition in which the polymer of the underfill composition was changed to an ethyl acrylate/acrylonitrile copolymer (Mw: 1,400,000, copolymerization ratio: 95:5) was used.

### Example 8

A multilayer interconnection board was produced in the same manner as in Example 1, except that the underfill composition 1 was changed to the following underfill composition 4.

Underfill composition 4

| | |
|---|---|
| Methyl ethyl ketone | 50 parts by mass |
| Ethyl acrylate/acrylonitrile copolymer (Mw: 160,000, | 14 parts by mass |
| copolymer molar ratio: 95:5) | |
| Epoxy resin (product name: BST001A, curing | 2 parts by mass |
| temperature: 150° C., manufactured by | |
| NAMICS CORPORATION) | |
| Maleimide compound (product name: BMI 5100, | 22 parts by mass |
| manufactured by Daiwa Kasei Industry Co., Ltd.) | |
| Bisallylphenol (product name: DABPA, manufactured | 12 parts by mass |
| by Daiwa Kasei Industry Co., Ltd.) | |

### Comparative Example 1

A multilayer interconnection board was produced in the same manner as in Example 1, except that the copolymerization ratio of acrylonitrile in the ethyl acrylate/acrylonitrile copolymer was changed to 0.

### Comparative Example 2

A multilayer interconnection board was produced in the same manner as in Example 1, except that a composition in which the polymer of the underfill composition was changed to an epoxy resin (product name: BST001A, curing temperature: 150° C., manufactured by NAMICS CORPORATION) was used.

### Comparative Example 3

A multilayer interconnection board was produced in the same manner as in Example 1, except that the underfill composition was not used.

### Evaluation

### Viscosity

The underfill compositions prepared in Examples 1 to 8 and Comparative Examples 1 to 3 were subjected to dynamic viscoelasticity measurement (device: Leometer DHR-2 manufactured by TA Instruments).

Specifically, using a parallel plate of 25 mmφ and a lower plate for environmental test chamber (ETC) (Gap: 0.5 mm), a melt viscosity was measured under conditions of a temperature (set value) of approximately 30° C. to 100° C., a heating rate of 5° C./min, a frequency of 1 Hz, and a strain of 0.5%, and a viscosity at 100° C. was measured. The measurements were performed four times, and an average value thereof was calculated. The results are shown in Table 1 below.

### Temporal Stability

After being left to stand for 72 hours in an environment of 25° C. and a relative humidity of 50%, a viscosity at 25° C. was measured by the above-described method.

A case where a rate of change in viscosity was less than 5% was evaluated as A, a case where the rate of change was 5% or more and less than 20% was evaluated as B, and a case where the rate of change was 20% or more was evaluated as C. The results are shown in Table 1 below.

### Bonding Suitability

By measuring a resistance value between the chip wiring lines, it was evaluated whether or not the electrical connection was made. The measurement results of the resistance values are shown in Table 1 below.

### Metal Adhesiveness

The underfill compositions prepared in Examples 1 to 8 and Comparative Examples 1 to 3 were applied onto a copper plate so as to have a thickness of 1 and then heated under conditions of 220° C. for 30 minutes to produce a sample.

Adhesion of the produced sample was evaluated in five stages according to the classification shown in FIG. 4 with reference to a cross-cut method described in JIS K5600-5-6. In this case, a notch interval was set to 1 mm. The results are shown in Table 1 below.

### Reliability

The produced multilayer interconnection board was subjected to a temperature cycle test under a condition of (−50° C./+200° C.) and evaluated according to the following standard. The results are shown in Table 1 below.
A: resistance value was measured every 10 cycles, and the rate of change in resistance value (resistance value in 50 cycles) was less than 10%.
B: resistance value was measured every 10 cycles, and the rate of change in resistance value (resistance value in 50 cycles) was 10% or more and less than 50%.
C: resistance value was measured every 10 cycles, and the rate of change in resistance value (resistance value in 50 cycles) was 50% or more.

TABLE 1

| | Underfill composition | | | | | | | |
|---|---|---|---|---|---|---|---|---|
| | Polymer | | | | | | | |
| | | Co- | Con- | | | | | |
| | | poly- | tent | | | | | |
| | | mer- | of | | | Bond- | | |
| | | ization | cyano | | Tem- | ing | Metal | |
| | | ratio of | group | Vis- | poral | suita- | adhe- | Re- |
| | | acrylo- | mmol/ | cosity | sta- | bility | sive- | lia- |
| | Type | nitrile | g | Pa · s | bility | Ω | ness | bility |
| Example 1 | Ethyl | 5 | 0.51 | 15 | A | 400 | 0 | A |
| | acrylate/ | | | | | | | |
| | acrylo- | | | | | | | |
| | nitrile | | | | | | | |
| Example 2 | Ethyl | 15 | 1.61 | 13 | A | 400 | 0 | A |
| | acrylate/ | | | | | | | |
| | acrylo- | | | | | | | |
| | nitrile | | | | | | | |
| Example 3 | Ethyl | 25 | 2.83 | 12 | A | 400 | 0 | A |
| | acrylate/ | | | | | | | |
| | acrylo- | | | | | | | |
| | nitrile | | | | | | | |
| Example 4 | Ethyl | 1 | 0.10 | 80 | A | 420 | 1 | A |
| | acrylate/ | | | | | | | |
| | acrylo- | | | | | | | |
| | nitrile | | | | | | | |
| Example 5 | Ethyl | 5 | 0.51 | 13 | A | 400 | 0 | A |
| | acrylate/ | | | | | | | |
| | acrylo- | | | | | | | |
| | nitrile | | | | | | | |
| Example 6 | Ethyl | 5 | 0.51 | 50 | A | 550 | 0 | A |
| | acrylate/ | | | | | | | |
| | acrylo- | | | | | | | |
| | nitrile | | | | | | | |
| Example 7 | Ethyl | 5 | 0.51 | 40 | A | 440 | 0 | A |
| | acrylate/ | | | | | | | |
| | acrylo- | | | | | | | |
| | nitrile | | | | | | | |
| Example 8 | Ethyl | 5 | 0.51 | 20 | B | 420 | 2 | A |
| | acrylate/ | | | | | | | |
| | acrylo- | | | | | | | |
| | nitrile | | | | | | | |
| | Epoxy | — | — | | | | | |
| | resin | | | | | | | |
| Com- | Ethyl | 0 | 0 | 130 | A | 500 | 4 | B |
| parative | acrylate | | | | | | | |
| Example 1 | | | | | | | | |
| Com- | Epoxy | — | — | 50 | C | 450 | 3 | A |
| parative | resin | | | | | | | |
| Example 2 | | | | | | | | |
| Com- | | — | — | — | — | 400 | — | C |
| parative | | | | | | | | |
| Example 3 | | | | | | | | |

From the results shown in Table 1, it was found that, in a case where the polymer not containing a cyano group was used, the metal adhesiveness was deteriorated (Comparative Examples 1 and 2). In particular, in Comparative Example 2 in which the epoxy resin was used, it was found that the temporal stability was also deteriorated.

In addition, it was found that, in a case where the underfill composition was not used, reliability of the multilayer interconnection board was deteriorated (Comparative Example 3).

On the other hand, it was found that, in a case where a polymer having a predetermined amount of the cyano group was used, an underfill composition in which the temporal stability was excellent and the metal adhesiveness was good was obtained (Examples 1 to 8).

In particular, from the comparison between Example 1 and Example 5, it was found that, in a case where the acrylic monomer was added to the underfill composition, the viscosity was lowered and the workability was improved.

In addition, from the comparison between Example 1 and Example 6, it was found that Example 1 in which a component soluble in the solvent contained in the underfill composition was 95% by mass or more with respect to the total mass of a non-volatile component had higher metal adhesiveness and improved bondability.

In addition, from the comparison between Example 1 and Example 7, it was found that Example 1 in which the weight-average molecular weight of the polymer was 100,000 to 1,200,000 had lower viscosity and improved workability.

In addition, from the comparison between Example 1 and Example 8, it was found that Example 1 in which the polymer was a thermosetting resin having a curable group other than an epoxy group had improved temporal stability and metal adhesiveness.

### EXPLANATION OF REFERENCES

1: anisotropically conductive bonding member
2: insulating base material
3: conduction path
4: underfill composition
4a: underfill composition after curing
6: thickness of insulating base material
11: semiconductor element
12: electrode
13: circuit board
14: electrode
30: multilayer interconnection board

What is claimed is:

1. An underfill composition comprising:
a polymer; and
a maleimide compound having a maleimide group,
wherein the polymer has a cyano group, and
a content of the cyano group included in 1 g of the polymer is 0.1 to 6 mmol/g.

2. The underfill composition according to claim 1,
wherein a total content of the polymer and the maleimide compound is 10% to 80% by mass with respect to a total mass of the underfill composition.

3. The underfill composition according to claim 1, further comprising:
a solvent,
wherein a component soluble in the solvent is 95% by mass or more with respect to a total mass of a non-volatile component.

4. The underfill composition according to claim 1,
wherein the polymer is a thermosetting resin having a curable group other than an epoxy group.

5. The underfill composition according to claim 1,
wherein the polymer has a repeating unit, and
the repeating unit has a side chain including a cyano group.

6. The underfill composition according to claim 1,
wherein the polymer has a repeating unit represented by Formula (1), 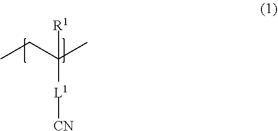
in Formula (1), R¹ represents a hydrogen atom or a substituent, and L¹ represents a single bond or a divalent linking group.

7. The underfill composition according to claim 1,
wherein a weight-average molecular weight of the polymer is 100,000 to 1,200,000.

8. The underfill composition according to claim 1,
wherein a content of the maleimide compound is 5% to 70% by mass with respect to a total mass of the underfill composition.

9. The underfill composition according to claim 1,
wherein the maleimide compound is a compound having two or more maleimide groups in one molecule.

10. The underfill composition according to claim 1,
wherein the maleimide compound is a bismaleimide compound.

11. The underfill composition according to claim 1, further comprising:
an allylphenol compound.

12. The underfill composition according to claim 11,
wherein a content of the allylphenol compound is 3% to 60% by mass with respect to a total mass of the underfill composition.

13. The underfill composition according to claim 1, further comprising:
at least one monomer selected from the group consisting of an acrylic monomer and a methacrylic monomer.

14. A coating film formed of the underfill composition according to claim 1.

15. A cured film formed by curing the coating film according to claim 14.

16. A multilayer interconnection board comprising, in the following order:
a semiconductor element having a plurality of electrodes;
an anisotropically conductive bonding member; and
a circuit board having a plurality of electrodes,
wherein the cured film according to claim 15 is disposed between the semiconductor element and the anisotropically conductive bonding member and between the circuit board and the anisotropically conductive bonding member,
the anisotropically conductive bonding member has an insulating base material consisting of an inorganic material and a plurality of conduction paths consisting of a conductive member, which penetrate through the insulating base material in a thickness direction and are provided in a state of being insulated from each other,
the plurality of conduction paths have a protruding portion protruding from a surface of the insulating base material, and
a height of the plurality of electrodes included in the circuit board is 10 μm or less.

17. The multilayer interconnection board according to claim 16,
wherein all of the conductive member of the anisotropically conductive bonding member, the plurality of electrodes included in the semiconductor element, and the plurality of electrodes included in the circuit board contain copper.

18. A manufacturing method of a multilayer interconnection board, in which a multilayer interconnection board having, in the following order, a semiconductor element having a plurality of electrodes, an anisotropically conductive bonding member, and a circuit board having a plurality of electrodes is manufactured, the manufacturing method comprising, in the following order:
a temporary bonding process of bonding the anisotropically conductive bonding member with the semiconductor element and the circuit board using the underfill composition according to claim 1;
a main bonding process of electrically bonding the conduction paths included in the anisotropically conductive bonding member with the plurality of electrodes included in the semiconductor element and the plurality of electrodes included in the circuit board by performing heating at a temperature lower than a curing temperature of the underfill composition; and
a curing process of curing the underfill composition by performing heating at a temperature equal to or higher than the curing temperature of the underfill composition,
wherein a temperature condition in the temporary bonding process is 20° C. to 140° C., and
a temperature condition in the main bonding process is a temperature higher than a temperature of the temporary bonding process.

19. The manufacturing method of a multilayer interconnection board according to claim 18,
wherein, in the temporary bonding process, coating films formed of the underfill composition are provided at surfaces of the anisotropically conductive bonding member on the semiconductor element side and on the circuit board side.

20. The manufacturing method of a multilayer interconnection board according to claim 18,
wherein, in the temporary bonding process, coating films formed of the underfill composition are provided at surfaces of the semiconductor element and the circuit board on the anisotropically conductive bonding member side.

21. The manufacturing method of a multilayer interconnection board according to claim 18,
wherein, in the main bonding process, the heating is performed after pressurization or in a pressurized state.
